(19) United States
(12) Patent Application Publication
(10) Pub. No.: US 2006/0087375 A1
(43) Pub. Date: Apr. 27, 2006

(54) Apparatus and method of controlling bias of power amplifier in mobile communication terminal

(75) Inventor: Seong-Beom Hong, Seoul (KR)

Correspondence Address: DILWORTH & BARRESE, LLP, 333 EARLE OVINGTON BLVD., UNIONDALE, NY, 11553, US

(73) Assignee: SAMSUNG ELECTRONICS CO., LTD., Suwon-si (KR)

(21) Appl. No.: 11/199,961

(22) Filed: Aug. 9, 2005

(30) Foreign Application Priority Data
Oct. 26, 2004 (KR) 2004-0085541

(51) Int. Cl. H03G 3/10

(52) U.S. Cl. 330/285

(57) ABSTRACT

Provided is an apparatus for controlling a bias of a power amplifier in a mobile communication terminal, which has the power amplifier for amplifying an input RF signal and an antenna for transmitting the amplified output RF signal. The apparatus includes a power detecting unit for detecting power output from the power amplifier and generating a control voltage based on the detected power, and a DC-DC converter for generating and applying a DC (Direct Current) voltage based on the control voltage of the power detecting unit, as a bias voltage of the power amplifier, wherein the power amplifier operates based on the bias voltage of the DC-DC converter to amplify and output the input RF signal.

### PRIORITY

This application claims priority under 35 U.S.C. § 119 to an application entitled “Apparatus And Method For Controlling Bias Of Power Amplifier” filed in the Korean Intellectual Property Office on Oct. 26, 2004 and assigned Ser. No. 2004-0085541, the contents of which are hereby incorporated by reference.

### BACKGROUND OF THE INVENTION

1. Field of the Invention

The present invention relates to an apparatus and method of controlling the bias of a power amplifier, and more particularly, to an apparatus and method of varying the bias voltage of a Radio Frequency (RF) power amplifier to minimize the current consumption in a mobile communication terminal.

2. Background of the Prior Art

The power consumption of a power amplifier is a main contributing factor in determining the lifetime of a battery in a mobile communication terminal. Generally, the power amplifier is designed by taking into consideration its power efficiency and linearity when a Radio Frequency (RF) output is maximized. That is, a class-AB power amplifier is designed to concurrently satisfy a maximum power efficiency and a linearity, and to fix an impedence matching and a bias state of each stage.

The mobile communication terminal is not always driven at a maximum output. For example, the mobile communication terminal has a variable transmission output depending on its distance from a base station and the speed at which a user is moving. In other words, in the case where the mobile communication terminal is disposed closely to the base station, a transmission output is relatively reduced. In the case where a user is a distance away from the base station within a cell radius or in the case where the user's moving speed is increased, the RF power level output is transmitted close to the maximum output of the amplifier.

FIG. 1 is a diagram illustrating a conventional apparatus for controlling the power amplifier by using a fixed bias in a mobile communication terminal.

Referring to FIG. 1, a power source supplying unit 103 applies the fixed bias voltage to power amplifiers 101 and 102. The current controlling unit 104 applies a fixed bias current to the power amplifiers 101 and 102. The power amplifiers 101 and 102 operate depending on a bias voltage and a bias current, which are applied from the power source supplying unit 103 and the current controlling unit 104, to power-amplify and output an input RF signal.

As such, the bias voltage and the bias current applied to the power amplifiers are fixed and used in the conventional art. In this case, since the power amplifiers have the bias voltage and the bias current fixed to a RF maximum output, a Power Added Efficiency (P.A.E.) of the power amplifier is greatly reduced when the RF output is small. This reduces the consumption of excessive DC power since the bias state of the power amplifier operating in class-AB at a maximum output level is substantially operated in class-A due to the reduction of an output level. In one of methods for solving the above drawback, a parallel or series-connected power amplifier is turned on/off in software to selectively operate depending on the output state.

FIG. 2 is a diagram illustrating a conventional apparatus of selectively operating the parallel-connected power amplifier depending on the output level in the mobile communication terminal.

Referring to FIG. 2, a Received Signal Strength Indication (RSSI) detecting unit 206 detects a RSSI received from a base station to provide the detected RSSI to the controlling unit 205. The controlling unit 205 outputs a switching signal for operating a corresponding amplifier, to switches 201 and 207 depending on the RSSI from the RSSI detecting unit 206. Additionally, the controlling unit 205 controls a power source supplying unit 208 to supply a corresponding driving power source (fixed bias voltage) to the corresponding amplifier, and to apply the fixed bias current to the corresponding amplifier. The switches 201 and 207 are switched under the control of the controlling unit 205 to provide the input RF signal to amplifiers 202 and 203 or an amplifier 204. The amplifiers 202 and 203 and the amplifier 204 power-amplify and output the input RF signal depending on the bias voltage and the bias current applied from the power source supplying unit 208 and the controlling unit 205.

Hereinafter, an operation of the construction of FIG. 2 is described.

If the RSSI detected in the RSSI detecting unit 206 is greater than a predetermined level, the input RF signal is power-amplified in the amplifier 204, which has a good efficiency in a lower power mode. At this time, a driving power source (Va1) supplied to the amplifiers 202 and 203 becomes 0V (Off). On the contrary, if the detected RSSI is less than the predetermined level, the input RF signal is power-amplified in the amplifiers 202 and 203 having a good efficiency in a high power mode. At this time, a driving power source (Va2) supplied to the amplifier 204 becomes 0V (Off). That is, in case where a low output is required due to a good RSSI, the amplifier 204 consuming a small DC power is used to reduce the current consumption.

A method of switching the series-connected amplifier is based on a similar concept. In the case where the low output is required, a bias voltage supplied to a rear-end amplifier of the series-connected amplifier is cut off to reduce the current consumption. After the RF signal is amplified at a front-end amplifier, the RF signal is bypassed directly to the RF output terminal (RFout), not through the rear-end amplifier.

### SUMMARY OF THE INVENTION

The above-described method of FIG. 2 has the following drawbacks.

First, the parallel-connected power amplifier has a drawback in that since the amplifier is additionally required, price and volume are increased. Further, since the parallel-connected power amplifier uses a fixed voltage/current bias, efficiency cannot be optimized.

Second, it is difficult to embody the parallel-connected power amplifier due to complexity of the circuit at two or more output levels. The parallel-connected power amplifier can increase the efficiency within a predetermined range, but has difficulty in optimization. In other words, a total power range is divided into a high gain mode and a low gain mode for use so that current consumption can be reduced in the low power mode. However, in the case where the total power range is divided into the high gain mode and the low gain mode, an intermediate value should be calibrated. During the calibration, a slope of the total power range is changed. Accordingly, there is a drawback of a timing compensation when “on/off” is performed for the duration of the calibration.

The present invention provides an apparatus and method of linearly varying a bias voltage of a power amplifier in a mobile communication terminal.

Also, the present invention provides an apparatus and method for varying a bias voltage of a power amplifier to minimize a current consumption in a mobile communication terminal.

Further, the present invention provides an apparatus and method for varying a bias voltage of a power amplifier depending on an output level in a mobile communication terminal.

According to an aspect of the present invention, there is provided an apparatus for controlling a bias of a power amplifier in a mobile communication terminal, which has a power amplifier for amplifying an input RF signal and an antenna for transmitting the amplified output RF signal, the apparatus includes a power detecting unit for detecting power output from the power amplifier, and generating a control voltage based on the detected power; and a DC-DC converter for generating and applying a DC (Direct Current) voltage based on the control voltage of the power detecting unit, as a bias voltage of the power amplifier, wherein the power amplifier operates based on the bias voltage of the DC-DC converter to amplify and output the input RF signal.

According to another aspect of the present invention, there is provided an apparatus for controlling a bias of a power amplifier in a mobile communication terminal, the apparatus includes a power detecting unit for detecting power output from the power amplifier, and generating a control voltage based on the detected power; a DC-DC converter for generating and applying a DC (Direct Current) voltage based on the control voltage of the power detecting unit, as a bias voltage of the power amplifier; a mixer for mixing a base band signal or an intermediate frequency signal with a modulation frequency to output a RF signal; a driving amplifier for initially amplifying the RF signal output from the mixer; and the power amplifier for operating based on the bias voltage of the DC-DC converter to secondarily amplify the initially amplified RF signal of the driving amplifier.

According to a further another aspect of the present invention, there is provided a method of controlling a bias of a power amplifier in a mobile communication terminal having the power amplifier, which operates based on an applied bias voltage to power-amplify an input RF signal to thereby generate a transmission signal, the method including the steps of detecting a power level output from the power amplifier; generating the bias voltage of the power amplifier based on the detected power level in a DC-DC converter; and supplying the generated bias voltage to a power source terminal (Vc) of the power amplifier.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a diagram illustrating a conventional apparatus of controlling a power amplifier with a fixed bias in a mobile communication terminal;

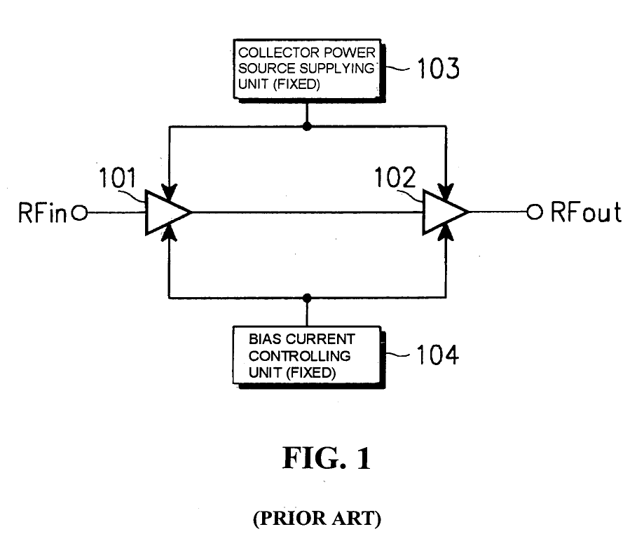

FIG. 2 is a diagram illustrating a conventional apparatus of selectively operating a parallel-connected power amplifier based on an output level in a mobile communication terminal;

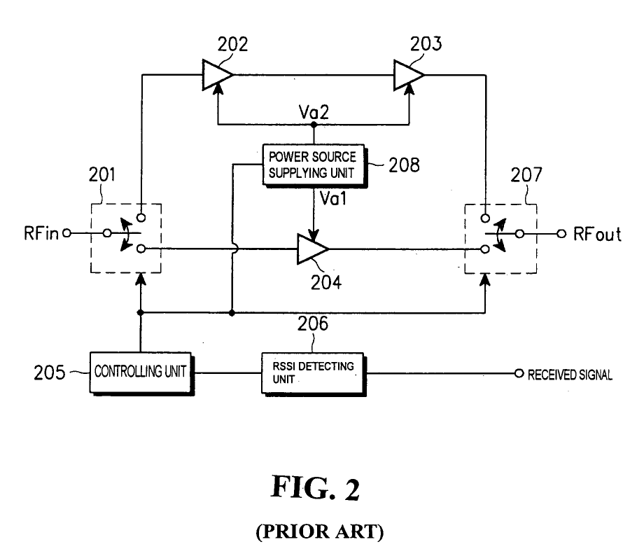

FIG. 3 is a diagram illustrating an apparatus of varying a bias voltage of a power amplifier based on an output level in a mobile communication terminal according to a preferred embodiment of the present invention;

FIG. 4 is a diagram illustrating an example of a construction of a power amplifier of FIG. 3;

FIG. 5 is a diagram illustrating a method of varying a bias of a power amplifier based on an output level in a mobile communication terminal according to a preferred embodiment of the present invention; and

FIG. 6 is a graph illustrating a bias voltage providing a maximum efficiency based on an output level.

### DETAILED DESCRIPTION OF THE PREFERRED EMBODIMENTS

Reference will now be made in detail to the preferred embodiments of the present invention, examples of which are illustrated in the accompanying drawings. Also, when it is determined that the subject of the invention may be obscured by a detailed description, the detailed description will be omitted.

Hereinafter, an apparatus for linearly varying a bias voltage of a power amplifier based on an output level in a mobile communication terminal is described. If a Direct Current (DC) bias voltage, which ideally should be supplied at a minimum value, can be varied within a range of voltage satisfying linearity, a current consumption can be minimized.

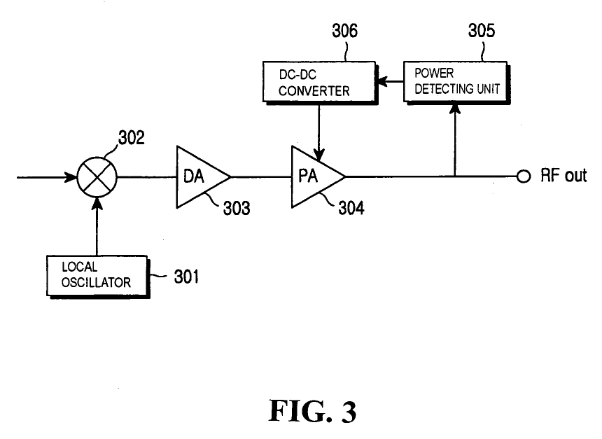

FIG. 3 is a diagram illustrating an apparatus for varying the bias voltage of the power amplifier based on an output level in the mobile communication terminal according to a preferred embodiment of the present invention.

A Radio Frequency (RF) front-end unit according to the present invention includes a local oscillator 301, a mixer 302, a driving amplifier 303, a power amplifier 304, a power detecting unit 305, and a DC-DC converter 306.

Referring to FIG. 3, an antenna (not shown) receives a signal from a base station or transmits a power-amplified RF output signal (transmission signal) to the base station. The local oscillator 301 generates a modulation frequency to output the generated modulation frequency to the mixer 302. The mixer 302 receives and mixes a base band signal (or intermediate frequency signal) with the modulation frequency output from the local oscillator 301, to output a Radio Frequency (RF) signal.

The driving amplifier 303 amplifies and outputs an output signal of the mixer 302 to input sufficient power to the power amplifier 304. The power amplifier 304 operates based on the bias voltage of the DC-DC converter 306 to power-amplify and output a RF signal of the driving amplifier 303.

The power detecting unit 305 detects the power output from the power amplifier 304, and outputs a control voltage based on the detected power to the DC-DC converter 306. The DC-DC converter 306 applies a DC voltage based on the control voltage of the power detecting unit 305, as the bias voltage of the power amplifier 304. As such, the DC-DC converter 306 supplies a different operation voltage (Vc: bias voltage) to the power amplifier 304 based on an output level of the power amplifier 304.

A coupler (not shown) can be included to couple the output of the power amplifier 304 to provide the coupled output to the power detecting unit 305, and can be included as a part of the power detecting unit 305.

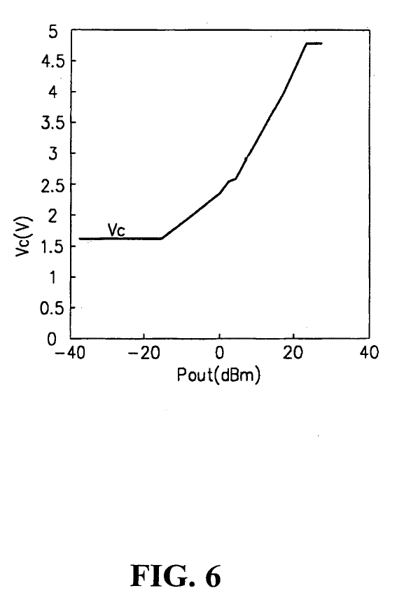

An optimal bias voltage based on the output level of the power amplifier 304 should be used. The optimal bias voltages based on the output level can be experimentally obtained (or measured), and an example thereof is illustrated in FIG. 6. FIG. 6 is a graph illustrating the bias voltage, which can provide a maximum efficiency (Power Added Efficiency: P.A.E.) based on an output level. As described above, according to the present invention, the DC-DC converter 306 is designed on the basis of the bias voltages obtained in the experiment.

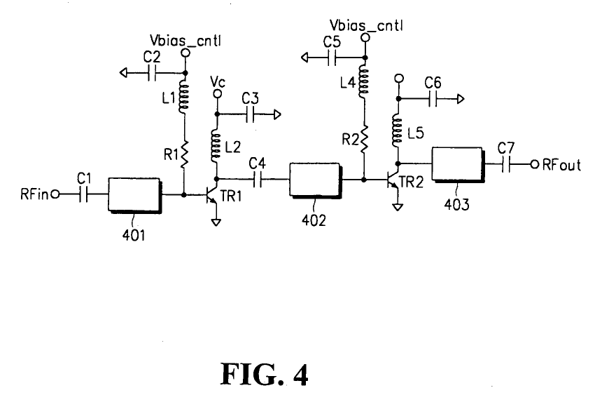

FIG. 4 is a detailed diagram illustrating an example of a construction of the power amplifier of FIG. 3.

Referring to FIG. 4, an RF input terminal (RFin) is connected to the base of a first transistor (TR1) through a capacitor (C1) and an input stage matching circuit 401, which are series-connected with each other. The capacitor (C1) couples an input signal, and the input stage matching circuit 401 matches the impedence between the input terminal (RFin) and the first transistor (TR1). A bias current control voltage terminal (Vbias_cnt1) is also connected to a base of the first transistor (TR1) through an inductor (L1) and a resistor (R1), which are series-connected with each other. A capacitor (C2) is connected between the bias current control voltage terminal and the ground. Here, the capacitor (C2) functions as a power source noise eliminating unit, and the inductance (L1) functions as a RF choke unit, and the resistor (R1) functions as a current limiting unit. A bias voltage control terminal (Vc) is connected to a collector of the first transistor (TR1) through an inductor (L2), and a capacitor (C3) is connected between the bias voltage control terminal (Vc) and the ground. Here, the capacitor (C3) functions as the power source noise eliminating unit, and the inductor (L2) functions as the RF choke unit. The first transistor (TR1) has an emitter connected to the ground, and a collector connected to a base of a second transistor (TR2) through a capacitor (C4) and an intermediate stage matching circuit 402, which are series-connected with each other. The capacitor (C4) couples an output signal of the first transistor (TR1), and the intermediate stage matching circuit 402 matches the impedence between an output terminal of the first transistor (TR1) and an input terminal of the second transistor (TR2).

The bias current control voltage terminal (Vbias_cnt1) is connected to the base of the second transistor (TR2) through an inductor (L4) and the resistor (R2), which are series-connected with each other, and a capacitor (C5) is connected between the bias current control voltage terminal and the ground. The capacitor (C5) functions as the power source noise eliminating unit, and the inductor (L4) functions as the RF choke unit, and the resistor (R2) functions as the current limiting unit. The bias voltage control terminal (Vc) is connected to a collector of the second transistor through the inductor (L4), and a capacitor (C6) is connected between the bias voltage control terminal (Vc) and the ground. The capacitor (C6) functions as the power source noise eliminating unit, and the inductor (L5) functions as the RF choke unit. The second transistor (TR2) has an emitter connected to the ground, and a collector connected to a RF output terminal (RFout) through an output stage matching circuit 403 and a capacitor (C7), which are series-connected with each other. Here, the output stage matching circuit 403 matches the impedence between the second transistor (TR2) and the output terminal (RFout), and the capacitor (C7) couples an output signal of the output stage matching circuit 403.

In the above construction of FIG. 4, the bias voltage output from the DC-DC converter 306 is supplied to each of the collectors (to each of drains in case where a Field Effect Transistor (FET) is used) of the first transistor (TR1) and the second transistor (TR2) of the power amplifier 304. The bias voltage output from the DC-DC converter 306 is provided to each of the bases (to each of gates in case where the FET is used) of the first transistor (TR1) and the second transistor (TR2) to concurrently control even the bias current.

A description of the operation of the device of FIGS. 3 and 4 will now be provided. The base band signal (or intermediate frequency signal) is mixed with the modulation frequency in the mixer 302 to be converted into the RF signal. The RF signal is amplified in the driving amplifier 303 and the power amplifier 304 to be output to the RF output terminal (RFout).

The power detecting unit 305 detects the power output from the power amplifier 304, and outputs the voltage based on the detected power to the DC-DC converter 306. The DC-DC converter 306 uses the voltage of the power detecting unit 305 as a control voltage to generate a corresponding DC voltage to the power amplifier 304. The DC voltage generated in the DC-DC converter 306 is supplied to each of the collectors (or to each of drains) of the first transistor (TR1) and the second transistor (TR2) of the power amplifier 304 to control the bias voltage of the power amplifier 304.

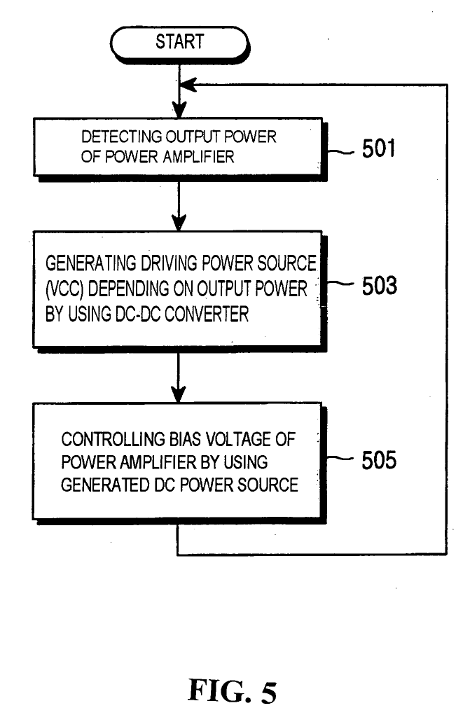

FIG. 5 is a diagram illustrating a method for varying the bias of the power amplifier based on the output level in the mobile communication terminal according to a preferred embodiment of the present invention.

Referring to FIG. 5, the communication terminal detects the power output from the power amplifier 304 in step 501. The output level of the power amplifier 304 is detected in the power detecting unit 305. The communication terminal generates the DC voltage based on the detected power in step 503. The DC voltage is generated in the DC-DC converter 306 for generating the different DC voltage based on the output level. After the communication terminal applies the DC voltage as the bias voltage of the power amplifier 304 in step 505, the terminal again returns to step 501 to again perform the subsequent steps. Alternatively, the power amplifier 304 operates based on the applied bias voltage to power-amplify and output the RF signal from the driving amplifier 303. The optimal bias voltages based on the output level of the power amplifier 304 can be experimentally obtained, and an example thereof is illustrated in FIG. 6.

An operation can be required for compensating for a gain which can be varied depending on the variation of the bias of the power amplifier 304. Such gain variation can be compensated by controlling the gain of an Auto Gain Controller (AGC) installed at a front end of the mixer 302. That is, the AGC compensates the gain variation of the power amplifier 304, which is generated by reducing the bias voltage to obtain the maximum efficiency according to the power level of the transmission signal as described above.

If the bias of the power amplifier 304 is controlled, the P.A.E based on the output level can be remarkably improved in comparison with a conventional maximal output fixed bias.

On the other hand, the conditions to be considered for embodying the present invention are as follows.

First, an original linearity [for example, Adjacent Channel Power Rejection (ACPR) and 3^{rd} order Inter-Modulation Distortion (IMD3)] of the power amplifier is maintained.

Second, a sudden variation of the bias voltage is refrained. The bias is selected within a range where a possible driving power source (Vc) is linearly varied depending on the output level to gradually and slowly vary the bias voltage. This allows for simplicity and reliability of the voltage control depending on the variation of the output level.

Third, the P.A.E. is maximized in a state where the above two conditions are satisfied.

As described above, the present invention has an advantage in that the voltage of the power amplifier is linearly varied depending on the total power range in hardware to minimize the current consumption depending on a power variation. Further, since the bias voltage is linearly controlled in the total power range, to linearly vary the gain and the voltage, even the slope of the total power range is linearly distributed to solve a timing drawback at the time of the power control.

The forgoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

What is claimed is:

1. An apparatus for controlling a bias of a power amplifier for amplifying an input RF signal, comprising:
a power detecting unit for detecting power output from a power amplifier, and generating a control voltage based on the detected power; and
a DC-DC converter for generating and applying a DC (Direct Current) voltage based on the control voltage of the power detecting unit, as a bias voltage of the power amplifier,
wherein the power amplifier operates based on the bias voltage of the DC-DC converter to amplify and output the input RF signal.

2. The apparatus of claim 1, wherein the DC-DC converter generates an optimal bias voltage based on an output level of the power amplifier, and the optimal bias voltage is experimentally obtained.

3. The apparatus of claim 1, further comprising a coupler for coupling an output of the power amplifier to provide the coupled output to the power detecting unit.

4. An apparatus for controlling a bias of a power amplifier in a mobile communication terminal, the apparatus comprising:
a power detecting unit for detecting power output from a power amplifier, and generating a control voltage depending on the detected power;
a DC-DC converter for generating and applying a DC (Direct Current) voltage based on the control voltage of the power detecting unit, as a bias voltage of the power amplifier;
a mixer for mixing one of a base band signal and an intermediate frequency signal with a modulation frequency to output a RF signal; and
a driving amplifier for amplifying the RF signal output from the mixer,
wherein the power amplifier operates based on the bias voltage of the DC-DC converter to secondarily amplify the amplified RF signal of the driving amplifier.

5. The apparatus of claim 4, wherein the DC-DC converter generates an optimal bias voltage based on an output level of the power amplifier, and the optimal bias voltage is experimentally obtained.

6. The apparatus of claim 4, further comprising a coupler for coupling an output of the power amplifier to provide the coupled output to the power detecting unit.

7. A method of controlling a bias of a power amplifier for amplifying an input RF signal, comprising the steps of:
detecting a power level output from a power amplifier;
generating a bias voltage for the power amplifier based on the detected power level in a DC-DC converter; and
supplying the generated bias voltage to a power source terminal (Vc) of the power amplifier.

8. The method of claim 7, wherein the DC-DC converter generates an optimal bias voltage based on an output level of the power amplifier, and the optimal bias voltage is experimentally obtained.

9. A method of controlling a bias of a power amplifier in a mobile communication terminal, comprising the steps of:
detecting a power level output from a power amplifier in a power detecting unit;
generating a bias voltage of the power amplifier based on the detected power level in a DC-DC converter;
mixing one of an input base band signal and intermediate frequency signal with a modulation frequency in a mixer to output a RF signal;
amplifying the RF signal of the mixer in a driving amplifier; and
operating the power amplifier based on the bias voltage of the DC-DC converter to secondarily amplify the amplified RF signal of the driving amplifier.

10. The method of claim 9, wherein the DC-DC converter generates an optimal bias voltage based on an output level of the power amplifier, and the optimal bias voltage is experimentally obtained.
